(19) United States
(12) Patent Application Publication
(10) Pub. No.: US 2025/0293578 A1
(43) Pub. Date: Sep. 18, 2025

(54) CIRCUIT AND METHOD FOR AUXILIARY WINDING FEEDBACK VOLTAGE KNEE POINT SAMPLING IN POWER CONVERTER

(71) Applicant: Chengdu Monolithic Power Systems Co., Ltd., Chengdu (CN)

(72) Inventor: Bin Xiao, Chengdu (CN)

(21) Appl. No.: 19/081,402

(22) Filed: Mar. 17, 2025

(30) Foreign Application Priority Data
Mar. 18, 2024 (CN) 202410309531.2

(51) Int. Cl. H02M 1/00; G01R 19/165; H02M 3/335

(52) U.S. Cl. CPC H02M 1/0025; G01R 19/16528; G01R 19/16538; H02M 3/33592

(57) ABSTRACT

The present application discloses a knee point sampling circuit for sampling a knee point of an auxiliary winding feedback voltage in a power converter, which includes a voltage offset circuit, a delay circuit, a comparison circuit and a sampling output circuit. The voltage offset circuit is configured to offset the auxiliary winding feedback voltage and output an offset auxiliary winding feedback voltage. The delay circuit is configured to delay the auxiliary winding feedback voltage and output a delayed auxiliary winding feedback voltage. The comparison circuit is configured to compare the offset auxiliary winding feedback voltage with the delayed auxiliary winding feedback voltage and output a comparison signal. The sampling output circuit is configured to sample the delayed auxiliary winding feedback voltage based on the comparison signal and output a knee point sampling signal being indicative of the knee point of the auxiliary winding feedback voltage.

### CROSS-REFERENCE TO RELATED APPLICATIONS

The present application claims priority to, and the benefit of, Chinese application No. 202410309531.2 filed on Mar. 18, 2024, which is incorporated herein by reference in its entirety.

### TECHNICAL FIELD

The present application relates to electronic circuits, and in particular, but not exclusively, to a knee point sampling circuit for sampling a knee point of an auxiliary winding feedback voltage in a power converter and a control circuit including the knee point sampling circuit.

### BACKGROUND

An isolated power converter is widely used in adapters and chargers with high safety requirements, which usually includes a primary circuit and a secondary circuit isolated by a transformer. FIG. 1 shows a typical isolated power converter 100, i.e., a flyback power converter 100. As shown in FIG. 1, the transformer T1 has a primary winding Lp and a secondary winding Ls. One terminal of the primary winding Lp is coupled to an input voltage Vi, and the other terminal is coupled to a reference ground through a primary switch PM1. The primary switch PM1 is controlled by a switching control signal. When the primary switch PM1 is turned on, the secondary winding Ls induces power from the primary winding Lp. When the primary switch PM1 is turned off, the secondary winding Ls provides the induced power to a load. A rectifier (shown as a diode) Ds is coupled in series with the secondary winding Ls to rectify the voltage on the secondary winding Ls while a capacitor Co smooth the rectified voltage to create the output voltage Vout. Because the primary and secondary sides are isolated, it is usually necessary to transmit signals between them through an isolation device such as an optocoupler device. In order to omit the isolation device for the purpose of cost reduction, many applications at present often adopt primary control mode. The flyback power converter 100 shown in FIG. 1 adopts a primary control mode, that is, the flyback power converter 100 obtains a feedback signal being indicative of the output voltage Vo by sensing a voltage on the secondary winding Ls by, for example, using an auxiliary winding Lt.

However, in this way, the voltage (for example, shown as a voltage Vzcd in FIG. 1, hereinafter referred to as an auxiliary winding feedback voltage Vzcd) induced through the auxiliary winding Lt actually indicates a sum of the output voltage Vo and a voltage drop (hereinafter referred to as a forward voltage drop VF) of a secondary rectifier Ds when the secondary rectifier Ds is forward-biased and allows current to pass through. That is, the auxiliary winding feedback voltage Vzcd sensed by the auxiliary winding Lt contains the forward voltage drop VF of the secondary rectifier Ds, which also varies with the current flowing through the secondary rectifier Ds. Therefore, the auxiliary winding feedback voltage Vzcd can't indicate the accurate output voltage Vo.

### SUMMARY

Based on the above problems, the present application provides a knee point sampling circuit for sampling a knee point of an auxiliary winding feedback voltage in a power converter. The knee point sampling circuit includes a voltage offset circuit, a delay circuit, a comparison circuit and a sampling output circuit. The voltage offset circuit is configured to receive the auxiliary winding feedback voltage, offset the auxiliary winding feedback voltage and output an offset auxiliary winding feedback voltage. The delay circuit is configured to receive the auxiliary winding feedback voltage, delay the auxiliary winding feedback voltage and output a delayed auxiliary winding feedback voltage. The comparison circuit is configured to compare the offset auxiliary winding feedback voltage with the delayed auxiliary winding feedback voltage and output a comparison signal. The sampling output circuit is configured to sample the delayed auxiliary winding feedback voltage based on the comparison signal and output a knee point sampling signal being indicative of the knee point of the auxiliary winding feedback voltage.

An embodiment of the present application further provides a control circuit of a power converter, which includes: a knee point sampling circuit as described above and which is configured to sample a knee point of an auxiliary winding feedback voltage in the power converter when the power converter works in a Discontinuous Conduction Mode or a Critical Current Mode, to provide a knee point sampling signal, a first sampling circuit, a difference circuit, a second sampling circuit, and a reference correction circuit. The first sampling circuit is configured to sample the auxiliary winding feedback voltage and output an auxiliary winding feedback voltage sampling signal. The difference circuit is configured to receive the auxiliary winding feedback voltage sampling signal and the knee point sampling signal, and output a forward voltage drop signal of a secondary rectifier based on the auxiliary winding feedback voltage sampling signal and the knee point sampling signal. The second sampling circuit is configured to receive a mode selection signal, sample the forward voltage drop signal when the mode selection signal indicates that the switch power supply is working in one of the Discontinuous Conduction Mode and the Critical Current Mode, and output a forward voltage drop sampling signal. The reference correction circuit is configured to receive a preset reference voltage and the forward voltage drop sampling signal, and output a reference correction voltage based on the preset reference voltage and the forward voltage drop sampling signal. When the power converter works in the continuous conduction mode, the control circuit outputs a switching control signal for controlling a control switch of the power converter based on the reference correction voltage and the auxiliary winding feedback voltage sampling signal.

The present application further provides a power converter, which includes: the control circuit as described above, a control switch, a primary winding, a secondary winding, and an auxiliary winding. The control switch is configured to receive the switching control signal and operate under control of the switching control signal. The primary winding is coupled to the control switch. The secondary winding is coupled to the secondary rectifier of the power converter. The auxiliary winding is configured to provide the auxiliary winding feedback voltage.

The present application further provides a method for sampling a knee point of an auxiliary winding feedback voltage in a power converter, which includes the following steps: offsetting the auxiliary winding feedback voltage to provide an offset auxiliary winding feedback voltage; delaying the auxiliary winding feedback voltage to provide a delayed auxiliary winding feedback voltage; comparing the offset auxiliary winding feedback voltage with the delayed auxiliary winding feedback voltage to provide a comparison signal; and sampling the delayed auxiliary winding feedback voltage based on the comparison signal to provide a knee point sampling signal being indicative of the knee point of the auxiliary winding feedback voltage.

In this way, by offsetting the auxiliary winding feedback voltage upward in advance and comparing it with the delayed auxiliary winding feedback voltage, an obviously decreased on the auxiliary winding feedback voltage can be determined when the offset auxiliary winding feedback voltage becomes smaller than the delayed auxiliary winding feedback voltage. In addition, when the offset auxiliary winding feedback voltage drops below the delayed auxiliary winding feedback voltage, it indicates that the knee point of the auxiliary winding feedback voltage has already arrived. And if the sampling operation is directly performed on the auxiliary winding feedback voltage, a value on the auxiliary winding feedback voltage value that has dropped obviously will be sampled. So, a more accurate knee point value of the auxiliary winding feedback voltage can be obtained by sampling the delayed auxiliary winding feedback voltage at this time.

### BRIEF DESCRIPTION OF DRAWINGS

In order to better understand the present application, the present application will be described in detail according to the following figures.

FIG. 1 shows the schematic circuit structure of an isolated power converter with primary control.

FIG. 2 shows a schematic waveform diagram 200 of the switching control signal and the auxiliary winding feedback voltage of the isolated power converter in Discontinuous Conduction Mode (DCM) or Critical Current Mode (CRM), according to an embodiment of the present application.

FIG. 3 shows a block diagram of a knee point sampling circuit for sampling the knee point of the auxiliary winding feedback voltage, according to an embodiment of the present application.

FIG. 4 shows a circuit diagram of a knee point sampling circuit for sampling the knee point of the auxiliary winding feedback voltage, according to an embodiment of the present application.

FIG. 5 shows a schematic waveform diagram 500 of some signals in the knee point sampling circuit, according to an embodiment of the present application.

FIG. 6 shows a schematic circuit structure of a power converter control circuit to which a knee point sampling circuit, according to an embodiment of the present application is applied.

FIG. 7 shows a flowchart of a method for sampling the knee point of the auxiliary winding feedback voltage in the power converter, according to an embodiment of the present application.

### DETAILED DESCRIPTION OF THE PRESENT APPLICATION

Hereinafter, specific embodiments of the present application will be described in detail, and it should be noted that the embodiments described here are only for illustration and are not used to limit the present application. In the following description, some specific details are included to provide a thorough understanding of embodiments. One skilled in the relevant art will identify, however, that the present application can be practiced without one or more specific details. In other instances, well-known structures, materials, processes or operations are not shown or described in detail to avoid obscuring aspects of the present application.

Throughout the specification and claims, the phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

In the following detailed description, for the sake of brevity, a flyback converter is taken as an example to explain the specific working principle of the present application. The present application can be applied to any kind of isolated power converter.

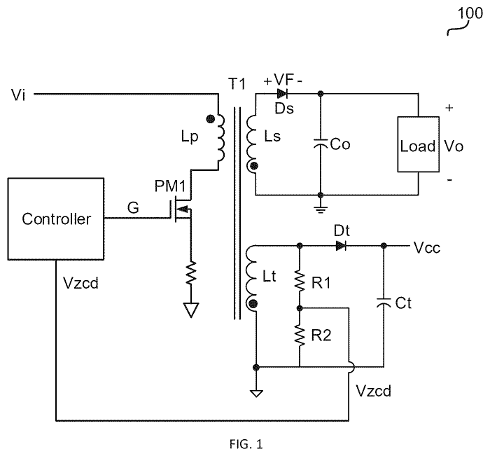

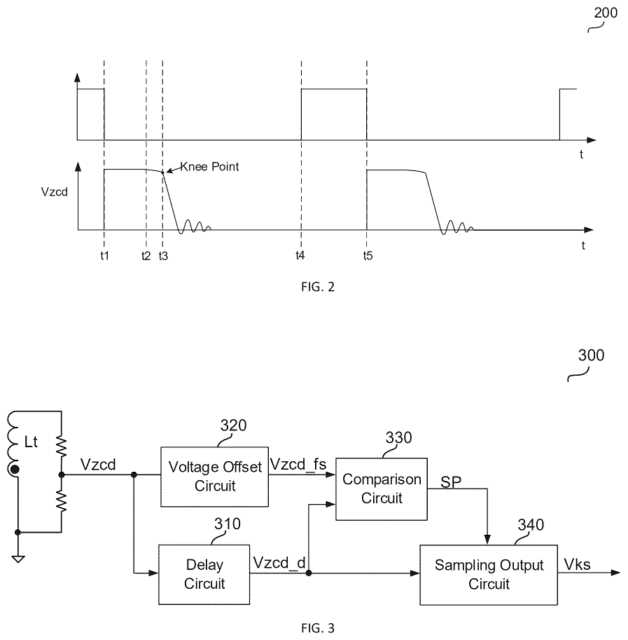

FIG. 2 shows a schematic waveform diagram 200 of the switching control signal and the auxiliary winding feedback voltage of the isolated power converter 100 with primary control in Discontinuous Conduction Mode (DCM) or Critical Current Mode (CRM), according to an embodiment of the present application. FIG. 2 is described with reference to FIG. 1.

In FIG. 2, time t1 is a start time of one switching period of the primary switch PM1 in the switch in the isolated power converter 100. As shown in FIG. 2, at the time t1, the switching control signal G is changed from high level to low level, and the switch PM1 is controlled to be turned off. At this time, the secondary rectifier Ds and an auxiliary diode Dt are forward-biased, and the auxiliary winding feedback voltage Vzcd starts to rise, which soon reaches a stable plateau value. At the initial moment when the secondary rectifier Ds and the auxiliary diode Dt are forward-biased, that is, at the initial stage when the auxiliary winding feedback voltage Vzcd rises, there will be a certain degree of oscillation on the auxiliary winding feedback voltage Vzcd before rising to the plateau value. To facilitate the description, such oscillation on the rising stage is not illustrated. Subsequently, since the power converter 100 operates in the DCM mode or the CRM mode, the current flowing through the secondary rectifier Ds will eventually decrease to zero. In the process of the current flowing through the secondary rectifier Ds reducing to zero, a voltage across the secondary rectifier Ds will begin to slowly decrease from a certain time (for example, time t2 in FIG. 2), and accordingly, the auxiliary winding feedback voltage Vzcd starts to decrease slowly. Until time t3, the secondary rectifier Ds and the auxiliary diode Dt are reverse-biased, i.e., no current is allowed to flow through, and then the auxiliary winding feedback voltage Vzcd starts to drop sharply. In the present disclosure, a point where a voltage value of the auxiliary winding feedback voltage Vzcd starts to drop significantly when the secondary rectifier Ds and the auxiliary diode Dt are reverse-biased is called a “knee point”. In the present application, we can also refer a moment when the secondary rectifier Ds and the auxiliary diode Dt are reverse-biased and the auxiliary winding feedback voltage Vzcd starts to drop significantly to a “knee point time” (for example, time t3 in FIG. 2). After the knee point time, auxiliary winding feedback voltage Vzcd rapidly drops to zero. At time t4, the switching control signal G is changed from low level to high level to turn on the control switch PM1, and the auxiliary winding feedback voltage Vzcd is maintained at zero. At time t5, the switching control signal G is changed from high level back to low level to turn off the switch PM1, and another switching period begins. It should be understood that when the power converter works in a Continuous Conduction Mode (CCM), the current flowing through the secondary rectifier Ds is not zero, and the auxiliary winding feedback voltage Vzcd will not drop as fast as at time t3 in FIG. 2, that is, when the power converter works in CCM, there is no such knee point.

As mentioned above, for the isolated power converter 100 with primary control as shown in FIG. 1, when the secondary rectifier Ds is forward-biased, the auxiliary winding feedback voltage Vzcd actually indicates the sum of the output voltage Vo, and the forward voltage drop VF of the secondary rectifier Ds. When the secondary rectifier Ds is reverse-biased, the current flowing through the secondary rectifier Ds is zero, and the voltage across it is also zero. At this time, the auxiliary winding feedback voltage Vzcd can reflect the accurate output voltage Vo. By using the auxiliary winding feedback voltage Vzcd at the time when the secondary rectifier Ds is reverse-biased, the error caused by the forward voltage drop of the secondary rectifier Ds can be eliminated, thus generating a more accurate switching control signal G.

FIG. 3 shows a block diagram of a knee point sampling circuit 300 for sampling the knee point of the auxiliary winding feedback voltage Vzcd, according to an embodiment of the present application. The knee point sampling circuit 300 is configured to sample the voltage of the auxiliary winding Lt at the time when the secondary rectifier Ds is reverse-biased (that is, the knee point time).

In one embodiment, as shown in FIG. 3, the knee point sampling circuit 300 include a delay circuit 310, a voltage offset circuit 320, a comparison circuit 330 and a sampling output circuit 340.

In one embodiment, the delay circuit 310 is configured to delay the auxiliary winding feedback voltage Vzcd. As shown in FIG. 3, the delay circuit 310 has an input terminal and an output terminal. The input terminal is configured to receive the auxiliary winding feedback voltage Vzcd and the output terminal is configured to provide a delayed auxiliary winding feedback voltage Vzcd_d. According to the embodiment of the present application, the delay circuit 310 can be any circuit that has a function for delaying signals.

In one embodiment, the voltage offset circuit 320 is configured to offset the auxiliary winding feedback voltage Vzcd. As shown in FIG. 3, the voltage offset circuit 320 includes an input terminal configured to receive the auxiliary winding feedback voltage Vzcd and an output terminal configured to provide an offset auxiliary winding feedback voltage Vzcd_fs. For example, by offsetting the auxiliary winding feedback voltage Vzcd, we can obtain the offset auxiliary winding feedback voltage Vzcd_fs that is always higher than the auxiliary winding feedback voltage Vzcd by a preset offset value Voffset, i.e., Vzcd_fs=Vzcd+Voffset. In one embodiment, the preset offset value Voffset may be determined in advance based on, for example, the actual circuit design and related circuit parameters of the comparison circuit 330 and the delay circuit 310. Specifically, because the comparison circuit 330 is always affected by an input offset voltage and noise in practical application, when the difference between the two input signals is too small, its resolution will decrease, causing the uncertainty of the state of the output signal. The output will be stable when the difference between the two input signals reaches a certain voltage value (which is defined as the input offset voltage of the comparator). Therefore, according to an embodiment of the present application, the preset offset value Voffset is set to be greater than the input offset voltage of the comparison circuit, so that the comparison circuit 330 can precisely obtain the state change of the comparison result when the offset auxiliary winding feedback voltage Vzcd_fs becomes smaller than the delayed auxiliary winding feedback voltage Vzcd_d, so as to indicate that the auxiliary winding feedback voltage Vzcd has changed significantly/dropped sharply. In addition, since the delayed (and also filtered) auxiliary winding feedback voltage Vzcd_d follows the changing trend of the auxiliary winding feedback voltage Vzcd, in order to avoid the sampling accuracy being reduced due to the backward movement of the sampling window, the preset offset value Voffset cannot be set too low. For example, by using the knee point sampling method according to the embodiment of the present application, the sampling accuracy can reach 99% by setting an appropriate preset offset value Voffset.

In one embodiment, the comparison circuit 330 is configured to compare the offset auxiliary winding feedback voltage Vzcd_fs with the delayed auxiliary winding feedback voltage Vzcd_d, and generate a comparison signal SP at its output according to the comparison result. As shown in FIG. 3, the comparison circuit 330 has a first input terminal, a second input terminal and an output terminal. The first input terminal of the comparison circuit 330 is coupled to the output terminal of the voltage offset circuit 320 to receive the offset auxiliary winding feedback voltage Vzcd_fs, the second input terminal of the comparison circuit 330 is coupled to the output terminal of the delay circuit 310 to receive the delayed auxiliary winding feedback voltage Vzcd_d, and the output terminal of the comparison circuit 330 is coupled to the sampling output circuit 340 to provide the comparison signal SP to the sampling output circuit 340.

In one embodiment, when the offset auxiliary winding feedback voltage Vzcd_fs becomes smaller than the delayed auxiliary winding feedback voltage Vzcd_d, the comparison signal SP changes to high level (or low level, depending on the implementation of the comparison circuit), indicating that the auxiliary winding feedback voltage Vzcd has changed significantly/dropped sharply. In one embodiment, the sampling output circuit 340 is configured to sample the delayed auxiliary winding feedback voltage Vzcd_d at this knee point time to provide a knee point sampling signal Vks.

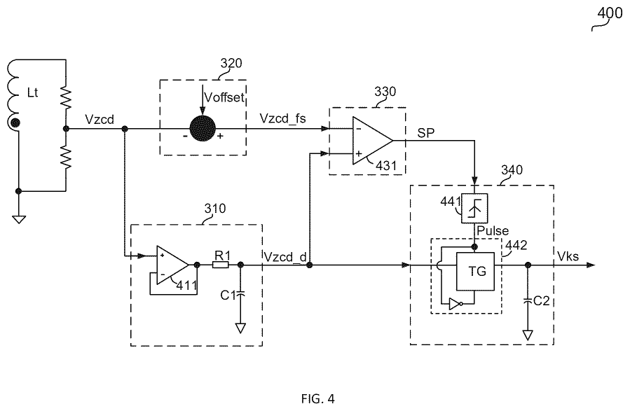

FIG. 4 shows a circuit diagram of the knee point sampling circuit 400 for sampling the knee point of the auxiliary winding feedback voltage Vzcd, according to an embodiment of the present application. FIG. 4 will be described in conjunction with FIG. 3. The knee point sampling circuit 400 is an embodiment of the knee point sampling circuit 300 shown in FIG. 3.

In the embodiment shown in FIG. 4, the delay circuit 310 includes an amplifier 411 (also referred to as a buffer amplifier), a resistor R1 (also referred to as a delay resistor) and a capacitor C1 (also referred to as a delay capacitor). As shown in FIG. 4, the amplifier 411 has a first input terminal (e.g., a noninverting input terminal), a second input terminal (e.g., an inverting input terminal) and an output terminal. The first input terminal is configured to receive the auxiliary winding feedback voltage Vzcd, and the second input terminal is coupled to the output terminal for buffering the auxiliary winding feedback voltage Vzcd received from the first input terminal. In one embodiment, the resistor R1 has a first terminal and a second terminal. The first terminal of the resistor R1 is coupled to the second input terminal and the output terminal of the amplifier 411 and the second terminal of the resistor R1 is coupled to the second input terminal of the comparison circuit 330. In one embodiment, the capacitor C1 has a first terminal and a second terminal. The first terminal of the capacitor C1 is coupled to the second terminal of the resistor R1, and the second terminal of the capacitor C1 is coupled to a reference ground. In one embodiment, the delay circuit 310 not only delays the auxiliary winding feedback voltage Vzcd, but also filters the signal to make the delayed auxiliary winding feedback voltage Vzcd_d smoother. It should be understood that the delay circuit 310 can include any circuit that can be used to delay the auxiliary winding feedback voltage Vzcd. For example, the delay circuit 310 can only include an RC circuit composed of a resistor and a capacitor. The present application is not limited thereto.

In the embodiment shown in FIG. 4, the voltage offset circuit 320 includes an offset voltage generating circuit (not shown) and an adding circuit. The offset voltage generating circuit is configured to generate an offset voltage Voffset, and the adding circuit is configured to receive the auxiliary winding feedback voltage Vzcd and add it to the offset voltage Voffset to provide the offset auxiliary winding feedback voltage Vzcd_fs. The voltage offset circuit 320 can be any circuit that offsets the auxiliary winding feedback voltage Vzcd upward, and the present application is not limited there to.

In the embodiment shown in FIG. 4, the comparison circuit 330 includes a comparator 431. In one embodiment, the comparator 431 has a first input terminal (e.g., an inverting input terminal), a second input terminal (e.g., non-inverting input terminal) and an output terminal. The first input terminal of the comparator 431 is coupled to the output terminal of the voltage offset circuit 320 to receive the offset auxiliary winding feedback voltage Vzcd_fs, and the second input terminal of the comparator 431 is coupled to the output terminal of the delay circuit 310 to receive the delayed auxiliary winding feedback voltage Vzcd_d. The comparator 431 is configured to compare the offset auxiliary winding feedback voltage Vzcd_fs with the delayed auxiliary winding feedback voltage Vzcd_d, and generate the comparison signal SP according to the comparison result. In the embodiment of FIG. 4, the delayed auxiliary winding feedback voltage Vzcd_d and the offset auxiliary winding feedback voltage Vzcd_fs are input to the non-inverting input terminal and the inverting input terminal of the comparator 431, respectively. When the offset auxiliary winding feedback voltage Vzcd_fs becomes smaller than the delayed auxiliary winding feedback voltage Vzcd_d, the comparison signal SP is changed to high level, and when the offset auxiliary winding feedback voltage Vzcd_fs becomes greater than the delayed auxiliary winding feedback voltage Vzcd_d the delayed auxiliary winding feedback voltage Vzcd_d, the comparison signal SP is changed to low level. It should be understood that in actual design, the delayed auxiliary winding feedback voltage Vzcd_d and the offset auxiliary winding feedback voltage Vzcd_fs can also be respectively input to the inverting input terminal and the non-inverting input terminal of the comparator 431, so that When the offset auxiliary winding feedback voltage Vzcd_fs becomes smaller than the delayed auxiliary winding feedback voltage Vzcd_d, the comparison signal SP is changed to low level, and when the offset auxiliary winding feedback voltage Vzcd_fs becomes greater than the delayed auxiliary winding feedback voltage Vzcd_d the delayed auxiliary winding feedback voltage Vzcd_d, the comparison signal SP is changed to high level. The present application is not limited thereto.

In the embodiment shown in FIG. 4, the sampling output circuit 340 includes a pulse generating circuit 441, a switch circuit 442 and a capacitor C2 (also referred to as an output capacitor). In one embodiment, the pulse generating circuit 441 includes a rising edge triggering circuit for providing a pulse signal Pulse in response to a rising edge of the comparison signal SP. In the embodiment shown in FIG. 4, the rising edge of the comparison signal SP indicates that the offset auxiliary winding feedback voltage Vzcd_fs becomes smaller than the delayed auxiliary winding feedback voltage Vzcd_d. The signal form of the comparison signal SP is different based on practical application. For example, when the offset auxiliary winding feedback voltage Vzcd_fs becomes smaller than the delayed auxiliary winding feedback voltage Vzcd_d, the comparison signal SP can also be changed from high level to low level. At this situation, the pulse generating circuit 441 may include a falling edge triggering circuit. The present disclosure is not limited thereto. As shown in FIG. 4, the pulse generating circuit 441 has an input terminal and an output terminal. The input terminal of the pulse generating circuit 441 is coupled to the output terminal of the comparison circuit 330 to receive the comparison signal SP, and the output terminal of the pulse generating circuit 441 is coupled to the switch circuit 442 to provide the pulse signal Pulse to the switch circuit 442. Since the offset auxiliary winding feedback voltage Vzcd_fs is higher than the auxiliary winding feedback voltage Vzcd by the preset offset value Voffset, the offset auxiliary winding feedback voltage Vzcd_fs is also higher than the delayed auxiliary winding feedback voltage Vzcd_d by the preset offset value Voffset when the secondary rectifier Ds is forward-biased (that is, when the knee point time has not yet arrived). Therefore, when the offset auxiliary winding feedback voltage Vzcd_fs becomes smaller than the delayed auxiliary winding feedback voltage Vzcd_d, it indicates that the auxiliary winding feedback voltage Vzcd has obviously decreased, that is, the knee point of the auxiliary winding feedback voltage Vzcd has arrived. If the auxiliary winding feedback voltage Vzcd is sampled at this time (for example, when the rising edge of the comparison signal SP comes high level), the auxiliary winding feedback voltage value that has obviously dropped will be sampled. However, since the delayed auxiliary winding feedback voltage Vzcd_d has delayed behind the auxiliary winding feedback voltage Vzcd, a more accurate knee point value can be obtained by sampling the delayed auxiliary winding feedback voltage Vzcd_d.

In one embodiment, the switch circuit 442 is configured to be turned on based on the pulse signal Pulse, and when turned on, the switch circuit 442 outputs the delayed auxiliary winding feedback voltage Vzcd_d as the knee point sampling signal Vks. As shown in FIG. 4, the switch circuit 442 includes an input terminal, an output terminal and a control terminal. The input terminal is coupled to the delay circuit 310 to receive the delayed auxiliary winding feedback voltage Vzcd_d, the control terminal is coupled to the pulse generating circuit 441 to receive the pulse signal Pulse, and the output terminal is configured to output the delayed auxiliary winding feedback voltage Vzcd_d at the moment when the switch circuit is turned on as the knee point sampling signal Vks. In a specific embodiment, as shown in FIG. 4, the switch circuit 442 may include a transmission gate TG and an inverter. The inverter is configured to invert the pulse signal Pulse. As shown in FIG. 4, the transmission gate TG has an input terminal, an output terminal and two control terminals configured to receive complementary signals. The first terminal is coupled to the output terminal of the delay circuit 310 to receive the delayed auxiliary winding feedback voltage Vzcd_d, and the two control terminals are configured to respectively receive the pulse signal Pulse and the inverted pulse signal, and the transmission gate TG is turned on under the control of the pulse signal Pulse and its inverted signal. For example, when the pulse signal Pulse is a positive pulse and its inverted signal is a negative pulse, the transmission gate is turned on, and its output terminal outputs the delayed auxiliary winding feedback voltage Vzcd_d. It should be understood that the switch circuit 442 may be any suitable circuit that is turned on based on the pulse signal Pulse received from the pulse generating circuit 441. For example, the switch circuit 442 may include a switching which can be turned on based on the pulse signal Pulse.

In one embodiment, the output capacitor C2 has a first terminal and a second terminal. The first terminal is coupled to the output terminal of the transmission gate TG and the second terminal is coupled to the reference ground. The output capacitor C2 is configured to output and hold the voltage value of the delayed auxiliary winding feedback voltage Vzcd_d at the moment when the switch circuit 442 is turned on, and which is used as the knee point sampling signal Vks. The sampling output circuit 340 shown in FIG. 4 is only for exemplary, and the present application can adopt any circuit structure for sampling signals.

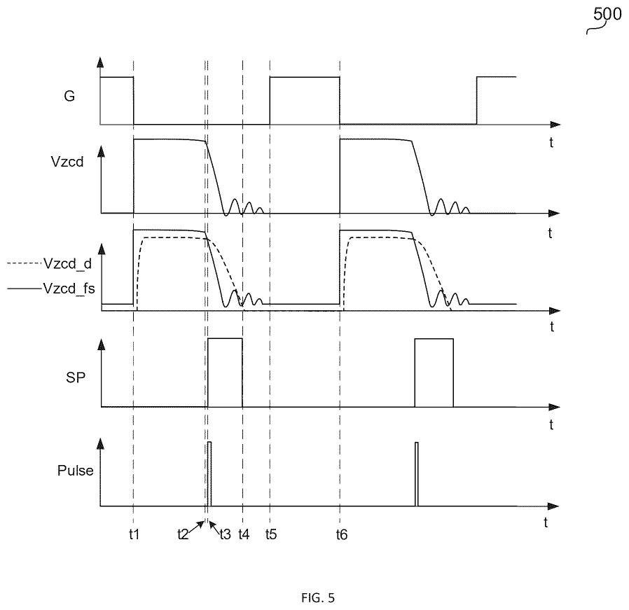

FIG. 5 shows a schematic waveform diagram 500 of some signals in the knee point sampling circuit 300, according to an embodiment of the present application. FIG. 5 will be described with reference to FIGS. 1, 3 and 4.

As shown in FIG. 5, at time t1, the switching control signal G is changed from high level to low level, the control switch M1 is turned off, the secondary rectifier Ds and the auxiliary diode Dt are forward-biased, and the auxiliary winding feedback voltage Vzcd is changed to high level, and then stabilizes at a plateau value. It should be understood that in the practical application scenario, at the initial moment when the secondary rectifier Ds and the auxiliary diode Dt are forward-biased, that is, the auxiliary winding feedback voltage Vzcd is in the initial stage of rising, there will be some initial oscillation on the auxiliary winding feedback voltage Vzcd, and then it will gradually basically stabilize at the plateau value. For the sake of simplicity, this initial oscillation is not shown in FIG. 5. As shown in FIG. 5, the offset auxiliary winding feedback voltage Vzcd_fs is offset upward, and changes after the auxiliary winding feedback voltage Vzcd. The delayed auxiliary winding feedback voltage Vzcd_d has a certain time delay relative to the auxiliary winding feedback voltage Vzcd. In addition, in one embodiment of the present application, the delay circuit 310 can not only delay the auxiliary winding feedback voltage Vzcd, but also filter the voltage Vzcd at the same time, so that the output delayed auxiliary winding feedback voltage Vzcd_d is smoother than the auxiliary winding feedback voltage Vzcd and the offset auxiliary winding feedback voltage Vzcd_fs. From time t1 to time t2, the offset auxiliary winding feedback voltage Vzcd_fs is greater than the delayed auxiliary winding feedback voltage Vzcd_d. At time t2, the secondary rectifier Ds is reverse-biased, and the auxiliary winding feedback voltage Vzcd starts to drop sharply. The offset auxiliary winding feedback voltage Vzcd_fs starts to drop synchronously and falls below the delayed auxiliary winding feedback voltage Vzcd_d in a short time (for example, at time t3). At this time, the comparison signal SP is changed from low level to high level, and the pulse generating circuit 441 generates a pulse signal Pulse (for example, a positive pulse signal) based on the rising edge of the comparison signal SP. The pulse signal Pulse is used to sample the delayed auxiliary winding feedback voltage Vzcd_d. As shown in FIG. 5, at time t3, the auxiliary winding feedback voltage Vzcd has obviously dropped, that is, the knee point of the auxiliary winding feedback voltage Vzcd has arrived. If the knee point sampling signal Vks is directly sampled from the auxiliary winding feedback voltage Vzcd, the value of the auxiliary winding feedback voltage that has dropped obviously will be sampled. A more accurate knee point value can be obtained by sampling the delayed auxiliary winding feedback voltage Vzcd_d at this time.

Subsequently, at time t4, the delayed auxiliary winding feedback voltage Vzcd_d becomes smaller than the offset auxiliary winding feedback voltage Vzcd_fs, and the comparison signal SP is changed from high level to low level. At time t5, the switching control signal G is changed from low level back to high level, and the control switch PM1 is turned on. At this time, the secondary rectifier Ds is reverse-biased, and the auxiliary winding feedback voltage Vzcd approaches zero. At time t6, the switching control signal G is changed from high level to low level again. The control switch PM1 is turned off, and another switching period begins.

As can be seen from the foregoing description, when the power converter works in DCM mode or CRM mode, the auxiliary winding feedback voltage Vzcd will drop sharply from the moment when the current flowing through the secondary rectifier Ds (or the auxiliary diode Dt) becomes zero. By offsetting and delaying the auxiliary winding feedback voltage Vzcd in advance and comparing the offset auxiliary winding feedback voltage with the delayed auxiliary winding feedback voltage, it can be determined that a rapid drop on the auxiliary winding feedback voltage occurs when the offset auxiliary winding feedback voltage becomes smaller than the delayed auxiliary winding feedback voltage. In addition, because the knee point time has passed by the time when the rapid drop is detected, a much smaller sampling voltage will be obtained if sampling operation is performed on the auxiliary winding feedback voltage. On the other hand, because the delayed auxiliary winding feedback voltage is lagging behind, a more accurate knee point value can be obtained by sampling the delayed auxiliary winding feedback voltage at this time.

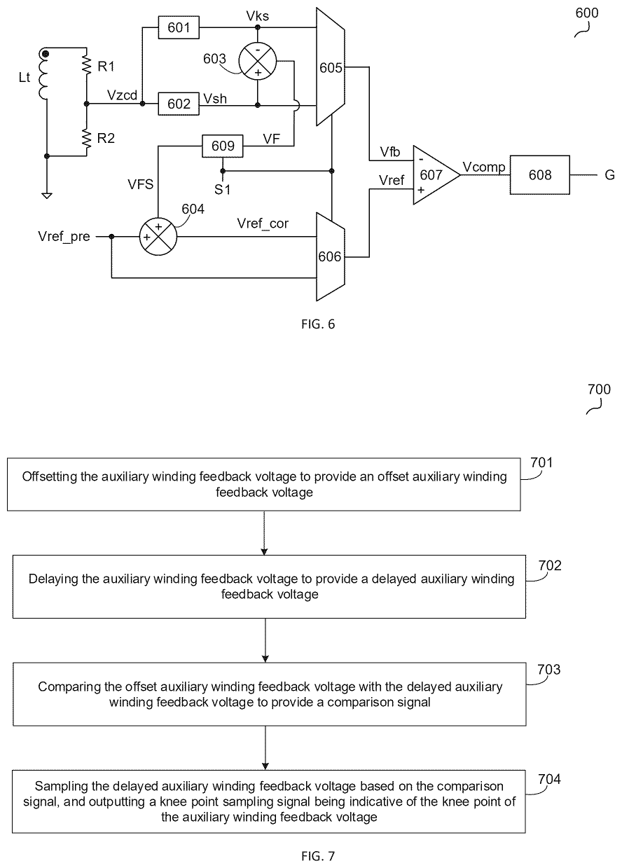

FIG. 6 shows a schematic circuit structure of a power converter control circuit 600 including the aforementioned knee point sampling circuit, according to an embodiment of the present application.

In one embodiment, as shown in FIG. 6, the control circuit 600 includes a knee point sampling circuit 601, a first sampling circuit 602, a difference circuit 603, a reference correction circuit 604, a first selection circuit 605, a second selection circuit 606, a differential amplification circuit 607, a switch control circuit 608, and a second sampling circuit 609.

The knee point sampling circuit 601 is configured to sample the knee point of the auxiliary winding feedback voltage Vzcd (for example, when the power converter works in the DCM mode or the CRM mode) to provide a knee point sampling signal Vks. The first sampling circuit 602 is configured to sample the auxiliary winding feedback voltage Vzcd and output an auxiliary winding feedback voltage sampling signal Vsh based on the sampling result. The difference circuit 603 is configured to receive the knee point sampling signal Vks and the auxiliary winding feedback voltage sampling signal Vsh and perform a subtraction operation on them to output a difference voltage, namely a forward voltage drop signal VF being indicative of a forward voltage drop of the secondary rectifier Ds. The second sampling circuit 609 is configured to receive a mode selection signal S1, sample the forward voltage drop signal VF when the mode selection signal S1 indicates that the power converter is in the DCM mode or in the CRM mode, and output a forward voltage drop sampling signal VFS. The reference correction circuit 604 is configured to receive a preset reference voltage Vref_pre and the forward voltage drop sampling signal VFS, and perform an addition operation on them to output a sum voltage, namely a reference correction voltage Vref_cor. The first selection circuit 605 is configured to receive the knee point sampling signal Vks, the auxiliary winding feedback voltage sampling signal Vsh and the mode selection signal S1, and select one of the knee point sampling signal Vks and the auxiliary winding feedback voltage sampling signal Vsh to output as a feedback voltage Vfb based on the mode selection signal S1. The second selection circuit 606 is configured to receive the reference correction voltage Vref_cor, the preset reference voltage Vref_pre and the mode selection signal S1, and select one of the reference correction voltage Vref_cor and the preset reference voltage Vref_pre to output as the reference voltage vref based on the mode selection signal S1. The differential amplification circuit 607 is configured to receive the feedback voltage Vfb and the reference voltage Vref, and outputs an error amplification signal Vcomp based on the feedback voltage Vfb and the reference voltage Vref. The switch control circuit 608 is configured to receive the error amplification signal Vcomp and output a switching control signal G based on the error amplification signal Vcomp. The switching control signal G is used to control the control switch PM1 of the power converter 100 shown in FIG. 1. The auxiliary winding feedback voltage Vzcd is indicative of the voltage on the auxiliary winding Lt.

During the DCM mode or the CRM mode, at the moment when the secondary rectifier Ds is reverse-biased, the auxiliary winding feedback voltage Vzcd begins to drop sharply, and the voltage value of the auxiliary winding feedback voltage Vzcd at the knee point is the knee point value. When the power converter works in the CCM mode, the knee point will not present. In the embodiment of FIG. 6, sampling of the knee point of the auxiliary winding feedback voltage Vzcd is performed by the knee point sampling circuit 601.

In the embodiment of FIG. 6, as mentioned above, when the secondary rectifier Ds is forward-biased, the auxiliary winding feedback voltage Vzcd actually indicates the sum of the output voltage Vo of the power converter and the forward voltage drop VF of the secondary rectifier Ds. During the DCM mode or the CRM mode, at the moment when the secondary rectifier Ds is reverse-biased, the current flowing through the secondary rectifier Ds is zero, such that the voltage across it is zero, that is, VF=0, and at this time, the auxiliary winding feedback voltage Vzcd is indicative of the output voltage Vo of the power converter. That is to say, when the power converter works in the DCM mode or the CRM mode, the knee point of the auxiliary winding feedback voltage Vzcd can accurately indicate the output voltage Vo of the power converter. However, when the power converter works in the CCM mode, the current flowing through the secondary rectifier Ds is not zero, so the forward voltage drop VF of the secondary rectifier Ds will not become zero, that is, when the power converter works in the CCM mode, the knee point value cannot be sampled. Therefore, in order to make the power converter get accurate feedback information of the output voltage Vo in all modes (for example, the DCM, CRM and CCM modes), it is necessary to obtain the forward voltage drop of the secondary rectifier Ds, and to eliminate this error in the subsequent circuits, so as to get accurate output voltage feedback.

In the embodiment of FIG. 6, when the selection signal S1 indicates that the power converter is working in the DCM mode or the CRM mode, the knee point sampling signal Vks does not contain the forward voltage drop VF of the secondary rectifier Ds, so it can accurately indicate output voltage Vo. Therefore, during these kind of modes (e.g., the DCM mode or the CRM mode), the first selection circuit 605 selects the knee point sampling signal Vks as the feedback voltage Vfb, and the second selection circuit 606 selects the preset reference voltage Vref_pre as the reference voltage Vref. Then the feedback voltage Vfb and the reference voltage Vref are input to the error amplifier 607 and which provides the error amplification signal Vcomp based on the feedback voltage Vfb and the reference voltage Vref. When the selection signal S1 indicates that the power converter works in the CCM mode, the first selection circuit 605 selects to output the auxiliary winding feedback voltage sampling signal Vsh as the feedback voltage Vfb, and the second selection circuit 606 selects to output the reference correction voltage Vref_cor as the reference voltage Vref. That is to say, when the power converter works in the CCM mode, the forward voltage drop VF of the secondary rectifier Ds is included in the preset reference voltage Vref_pre, so that the error caused by the forward voltage drop VF is eliminated. In order to stabilize the value of forward voltage drop VF, the second sampling circuit 609 is configured to sample and hold the forward voltage drop VF when the mode selection signal S1 indicates that the power converter is working in the DCM mode or the CRM mode, and provide the forward voltage drop sampling signal VFS of the secondary rectifier. After the power converter enters the CCM mode, the forward voltage drop sampling signal VFS is used to correct the value of the preset reference voltage Vref_pre to obtain the reference correction voltage Vref_cor, and the reference correction voltage Vref_cor and the auxiliary winding feedback voltage sampling signal Vsh selected as the feedback voltage Vfb are input into the error amplifier to provide the error amplification signal Vcomp.

In the embodiment of FIG. 6, the switch control circuit 608 is configured to receive the error amplification signal Vcomp and generate the switching control signal G based on the error amplification signal Vcomp for controlling the control switch PM1 of the power converter. The switch control circuit 608 includes any suitable control circuit for adjusting the frequency and/or duty ratio of the switching control signal G according to the feedback signal (such as a peak current control circuit, a voltage control circuit, an average current control circuit, a fixed on/off time control circuit, and the like) to regulate the output voltage of the power converter to a desired voltage level.

FIG. 7 shows a flowchart of a method 700 for sampling a knee point of an auxiliary winding feedback voltage in a power converter, according to an embodiment of the present application. FIG. 7 will be described with reference to FIGS. 2 to 6. The method 700 includes the following steps 701 to 704: step 701, offsetting the auxiliary winding feedback voltage to provide an offset auxiliary winding feedback voltage; step 702, delaying the auxiliary winding feedback voltage to provide a delayed auxiliary winding feedback voltage. step 703, comparing the offset auxiliary winding feedback voltage with the delayed auxiliary winding feedback voltage to provide a comparison signal; step 704, sampling the delayed auxiliary winding feedback voltage based on the comparison signal, and outputting a knee point sampling signal being indicative of the knee point of the auxiliary winding feedback voltage.

It should be understood that there is no sequential relationship between the above steps in the above method 700 according to the embodiment of the present application.

Although some embodiments of the present application have been described in detail above, it should be understood that these embodiments are only for illustrative purposes and are not used to limit the scope of the present application. Other feasible alternative embodiments can be known to those of ordinary skill in the art by reading the present disclosure.

1. A knee point sampling circuit for sampling a knee point of an auxiliary winding feedback voltage in a power converter, comprising:
a voltage offset circuit, configured to receive the auxiliary winding feedback voltage, offset the auxiliary winding feedback voltage, and output an offset auxiliary winding feedback voltage;
a delay circuit, configured to receive the auxiliary winding feedback voltage, delay the auxiliary winding feedback voltage, and output a delayed auxiliary winding feedback voltage;
a comparison circuit, configured to compare the offset auxiliary winding feedback voltage with the delayed auxiliary winding feedback voltage, and output a comparison signal; and
a sampling output circuit, configured to sample the delayed auxiliary winding feedback voltage based on the comparison signal, and output a knee point sampling signal being indicative of the knee point of the auxiliary winding feedback voltage.

2. The knee point sampling circuit according to claim 1, wherein the voltage offset circuit comprises:
an adding circuit, configured to perform addition operation on the auxiliary winding feedback voltage and an offset voltage, and provide the offset auxiliary winding feedback voltage to a first input terminal of the comparison circuit.

3. The knee point sampling circuit according to claim 2, wherein the offset voltage is set to be greater than an input offset voltage of the comparison circuit.

4. The knee point sampling circuit according to claim 1, wherein the delay circuit comprises:
a buffer amplifier, having a first input terminal, a second input terminal and an output terminal, wherein the first input terminal is configured to receive the auxiliary winding feedback voltage, and the second input terminal is coupled with the output terminal;
a delay resistor, having a first terminal and a second terminal, wherein the first terminal of the delay resistor is coupled to the second input terminal and the output terminal of the buffer amplifier, and the second terminal of the delay resistor is coupled to a second input terminal of the comparison circuit; and
a delay capacitor, having a first terminal and a second terminal, wherein the first terminal of the delay capacitor is coupled to the second terminal of the delay resistor and the second terminal of the delay capacitor is coupled to a reference ground.

5. The knee point sampling circuit according to claim 1, wherein the sampling output circuit comprises:
a pulse generating circuit, coupled to the comparison circuit to receive the comparison signal from the comparison circuit and configured to generate a pulse signal based on the comparison signal;
a switch circuit, having an input terminal, an output terminal and a control terminal, wherein the input terminal is coupled to the delay circuit to receive the delayed auxiliary winding feedback voltage, and the control terminal is coupled to the pulse generating circuit to receive the pulse signal, wherein the switch circuit is turned on based on the pulse signal to output the knee point sampling signal at the output terminal; and
an output capacitor, having a first terminal and a second terminal, wherein the first terminal of the output capacitor is coupled to the output terminal of the switch circuit and the second terminal of the output capacitor is coupled to a reference ground.

6. A control circuit of a power converter, comprising:
a knee point sampling circuit, configured to sample a knee point of an auxiliary winding feedback voltage in the power converter when the power converter works in a Discontinuous Conduction Mode or a Critical Current Mode, and to provide a knee point sampling signal, wherein the knee point sampling circuit comprises:
a voltage offset circuit, configured to receive the auxiliary winding feedback voltage, offset the auxiliary winding feedback voltage and output an offset auxiliary winding feedback voltage;
a delay circuit, configured to receive the auxiliary winding feedback voltage, delay the auxiliary winding feedback voltage, and output a delayed auxiliary winding feedback voltage;
a comparison circuit, configured to compare the offset auxiliary winding feedback voltage with the delayed auxiliary winding feedback voltage, and output a comparison signal; and
a sampling output circuit, configured to sample the delayed auxiliary winding feedback voltage based on the comparison signal, and output the knee point sampling signal being indicative of the knee point of the auxiliary winding feedback voltage.

7. The control circuit according to claim 6, further comprising:
a first sampling circuit, configured to sample the auxiliary winding feedback voltage and output an auxiliary winding feedback voltage sampling signal;
a difference circuit, configured to receive the auxiliary winding feedback voltage sampling signal and the knee point sampling signal, and output a forward voltage drop signal of a secondary rectifier based on the auxiliary winding feedback voltage sampling signal and the knee point sampling signal;
a second sampling circuit, configured to receive a mode selection signal, sample the forward voltage drop signal when the mode selection signal indicates that the switch power supply is working in one of the Discontinuous Conduction Mode and the Critical Current Mode, and output a forward voltage drop sampling signal;
a reference correction circuit, configured to receive a preset reference voltage and the forward voltage drop sampling signal, and output a reference correction voltage based on the preset reference voltage and the forward voltage drop sampling signal;
wherein when the power converter works in a Continuous Conduction Mode, the control circuit outputs a switching control signal for controlling a control switch of the power converter based on the reference correction voltage and the auxiliary winding feedback voltage sampling signal.

8. The control circuit according to claim 7, further comprising:
a first selection circuit, configured to receive the auxiliary winding feedback voltage sampling signal, the knee point sampling signal and the mode selection signal, and select to output one of the auxiliary winding feedback voltage sampling signal and the knee point sampling signal as a feedback voltage based on the mode selection signal;
a second selection circuit, configured to receive the reference correction voltage, the preset reference voltage and the mode selection signal, and select to output one of the reference correction voltage and the preset reference voltage as a reference voltage based on the mode selection signal;
a differential amplification circuit, configured to receive the feedback voltage and the reference voltage, and output an error amplification signal based on the feedback voltage and the reference voltage; and
a switch control circuit, configured to receive the error amplification signal and output the switching control signal based on the error amplification signal.

9. A method for sampling a knee point of an auxiliary winding feedback voltage in a power converter, comprising:
offsetting the auxiliary winding feedback voltage to provide an offset auxiliary winding feedback voltage;
delaying the auxiliary winding feedback voltage to provide a delayed auxiliary winding feedback voltage;
comparing the offset auxiliary winding feedback voltage with the delayed auxiliary winding feedback voltage to provide a comparison signal; and
sampling the delayed auxiliary winding feedback voltage based on the comparison signal to provide a knee point sampling signal being indicative of the knee point of the auxiliary winding feedback voltage.
